(19) United States
(12) Patent Application Publication
(10) Pub. No.: US 2009/0142675 A1
(43) Pub. Date: Jun. 4, 2009

(54) RETICLE FOR OPTICAL PROXIMITY CORRECTION TEST PATTERN AND METHOD OF MANUFACTURING THE SAME

(75) Inventor: Jong Doo KIM, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/254,296

(22) Filed: Oct. 20, 2008

(30) Foreign Application Priority Data
Dec. 3, 2007 (KR) 10-2007-0124441

(51) Int. Cl. G03F 1/00

(52) U.S. Cl. 430/5

(57) ABSTRACT

A reticle for an Optical Proximity Correction (OPC) test pattern and a method of manufacturing the same. In one example embodiment of the present invention, a reticle for an OPC test pattern includes test patterns formed apart from each other at regular intervals and dummy patterns for controlling a light transmission amount formed between the test patterns. The dummy patterns are formed apart from the test patterns at a predetermined interval.

### CROSS-REFERENCE TO A RELATED APPLICATION

This application claims the benefit of Korean Patent Application No. 10-2007-0124441, filed on Dec. 3, 2007 which is hereby incorporated by reference as if fully set forth herein.

### BACKGROUND

1. Field of the Invention

Embodiments of the present invention relate to a reticle for a semiconductor device. In particular, embodiments of the present invention relate to a reticle for an Optical Proximity Correction (OPC) test pattern and a method of manufacturing the same.

2. Description of the Related Art

In recent years, with a reduction in size of devices integrated into a semiconductor chip and a reduction in the minimum line width of connection lines, it has become difficult to avoid an optical proximity effect in a pattern formed on a wafer using photolithography technology that uses ultraviolet rays. For example, the ultraviolet rays and I-rays have a wavelength of about 0.365 μm, but the minimum line width may be 0.35 μm. Accordingly, pattern distortion due to diffraction and interference may severely limit the manufacturing process of semiconductor devices. Such distortion caused by pattern proximity becomes serious with further reduction in minimum line width. In order to solve this problem, an optical proximity correction (OPC) process may be performed.

An OPC process is a technology for implementing a desired circuit pattern on a wafer by correcting distortion, such as refraction and diffraction, due to optical characteristics in a semiconductor manufacturing process. In particular, an OPC process can be employed in a photolithography process in which a complex electrical circuit is drawn on a silicon wafer substrate. With reliable implementation of an integrated circuit having a fine line width, the wavelength of light used in mask exposure may become longer than a feature size of a chip. For example, an OPC process may selectively distort the shape of the photomask in order to reduce refraction due to the extended wavelength of light, such that the circuit pattern is reliably implemented. The OPC process may be used at a place where the line width changes on a chip.

In recent years, with advancement of small and lightweight high-end electronic devices, high-end semiconductors have been developed. High-end semiconductors include semiconductors having a circuit line width of about 90 nm or less and System On Chip (SOC) semiconductors, in which multiple functions are implemented within a single chip. For this reason, OPC technology for accurately patterning a complex semiconductor circuit on a substrate has become increasingly important.

In a typical OPC process, an OPC test pattern is manufactured and a Critical Dimension (CD) data for OPC modeling is acquired. Accordingly, if the OPC test pattern is incorrectly manufactured, the accuracy of the OPC process may be degraded, and the optical proximity effect may not be appropriately corrected, resulting in a flawed photolithography process. In manufacturing the OPC test pattern, an optical proximity effect known as a flare effect becomes important with fine patterns. A flare effect is a phenomenon in which an unnecessary light component adversely affects pattern formation due to a lack of uniformity in a lens material, a design problem, or a manufacturing problem.

FIG. 1 is a partial detail view of a prior art reticle 1 for an OPC test pattern. As shown in FIG. 1, the patterns 2 of the reticle 1 are formed apart from each other at regular intervals D and d. As the intervals between the patterns are increased, the amount of light transmission increases, and thus the flare effect increases. The increase in the flare effect causes a difference in background intensity. FIG. 2 is a diagram showing a change in an aerial image depending on a flare effect. As shown in FIG. 2, an aerial image is changed, as compared with a case in which no flare effect occurs. As a result, a difference in CD data is observed in FIG. 2.

### SUMMARY OF EXAMPLE EMBODIMENTS

In general, example embodiments of the present invention relate to a reticle for an Optical Proximity Correction (OPC) test pattern and a method of manufacturing the same. Some example embodiments of the present invention are capable of improving a margin and a yield in a photolithography process by using an optimum OPC test pattern for optical proximity correction.

In one example embodiment of the present invention, a reticle for an OPC test pattern includes test patterns formed apart from each other at regular intervals and dummy patterns for controlling a light transmission amount formed between the test patterns. The dummy patterns are formed apart from the test patterns at a predetermined interval.

In another example embodiment of the present invention, a method of manufacturing a reticle for an OPC test pattern includes various steps. First, test patterns are formed apart from each other at regular intervals. Then, dummy patterns for controlling a light transmission amount are formed in a predetermined shape between the test patterns. The dummy patterns are formed apart from the test patterns at a predetermined interval.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

Aspects of example embodiments of the present invention will become apparent from the following detailed description of example embodiments given in conjunction with the accompanying drawings, in which:

FIG. 1 is a partial detail view of a prior art reticle for an OPC test pattern;

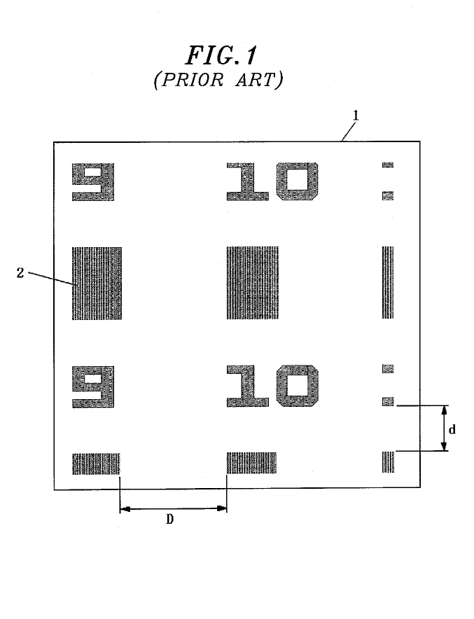

FIG. 2 is a diagram showing a change in an aerial image depending on a flare effect;

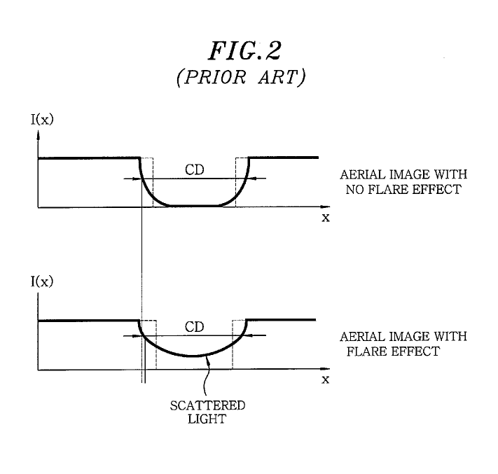

FIG. 3 is a partial detail view showing and example reticle for an OPC test pattern; and

FIG. 4 is a partial detail view showing another example reticle for an OPC test pattern.

### DETAILED DESCRIPTION OF EXAMPLE EMBODIMENTS

In general, example embodiments of the present invention relate to a reticle for an OPC test pattern and a method of manufacturing the same. In the following detailed description of the embodiments, reference will now be made in detail to specific embodiments of the present invention, examples of which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

### I. First Example Reticle

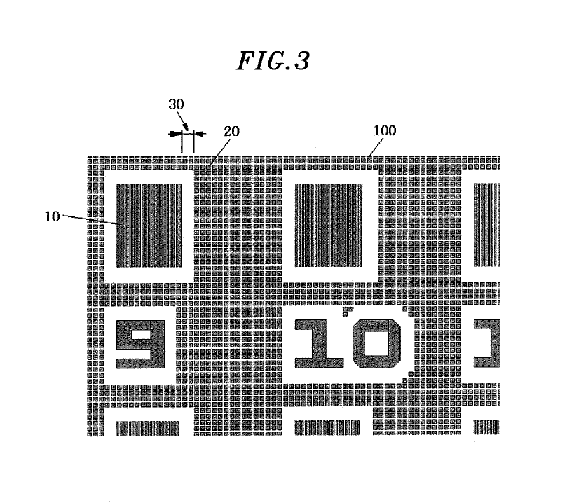

FIG. 3 is a partial detail view showing a first example reticle 100 for an OPC test pattern. Referring to FIG. 3, the example reticle 100 for an OPC test pattern includes test patterns 10 formed to be apart at regular intervals from each other, and dummy patterns 20 for controlling a light transmission amount formed in a predetermined shape between the test patterns 10. The dummy patterns 20 are formed to be apart at a predetermined interval 30 from the test patterns 10.

In the example reticle 100 manufactured in the above-described manner, a light transmission amount is controlled by the dummy patterns 20 for controlling a light transmission amount, which are formed in a predetermined shape between the test patterns 10 formed to be apart at regular intervals from each other, and thus a flare effect is reduced.

The interval 30 between the test patterns 10 and the dummy patterns 20 formed between the test patterns 10 may be in a range between about 0.8 μm and about 1.5 μm. For example, the interval 30 may be about 1 μm. Therefore, an optical effect of the dummy patterns 20 on the test patterns 10 is suppressed. In an isocline, if the interval 30 is less than about 0.8 μm, a desired pattern may not be obtained due to the dummy patterns 20. Meanwhile, if the interval 30 is more than about 1.5 μm, a desired CD may not be obtained.

In addition, since a chip has a different pattern density, it is preferable that light transmission density in the test pattern 10 is the same as that in a chip where an optical proximity correction process is employed.

According to this embodiment, as will be apparent from FIG. 3, the dummy patterns 20 are formed in a rectangular shape to control the light transmission amount.

### II. Second Example Reticle

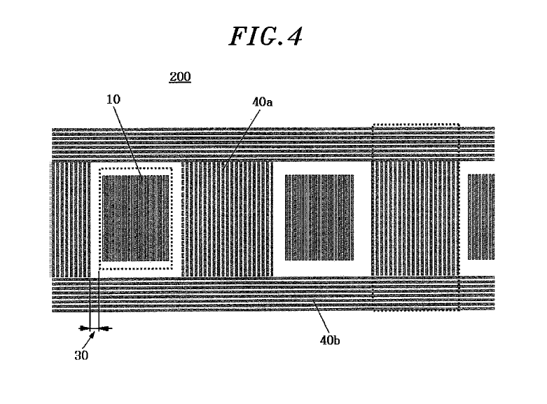

FIG. 4 is a partial detail view showing a second example reticle 200 for an OPC test pattern. Referring to FIG. 4, the example reticle 200 for an OPC test pattern includes test patterns 10 formed to be apart at regular intervals from each other, and dummy patterns 40a and 40b for controlling a light transmission amount formed in a predetermined shape between the test patterns 10. The dummy patterns 40a and 40b are formed at a predetermined interval 30 from the test patterns 10.

In the example reticle 200, as shown in FIG. 4, the dummy patterns 40a and 40b are formed in the shape of multiple horizontal or vertical lines. In particular, dummy patterns 40a are formed in the shape of horizontal lines, and dummy patterns 40b are formed in the shape of horizontal and vertical lines. With this structure, the light transmission amount in the OPC test patterns 10 can be controlled. The interval 30 between the OPC test patterns 10 and the dummy patterns 40a and 40b may be maintained in a range between about 0.8 μm to about 1.5 μm. Therefore, an optical effect of the dummy patterns 40a and 40b on the test patterns is suppressed. It is preferable that light transmission density in the test pattern 10 is the same as that in a chip where an optical proximity correction process is employed.

As disclosed herein, some example embodiments enable OPC modeling data to be obtained in the same optical environment as the main chip, i.e., real product database pattern. Therefore, errors in optical proximity correction are reduced, and as a result, the photolithography process is stabilized and electrical characteristics and yield are improved. Further, control of the amount of light transmission may be improved thus reducing a flare effect.

Although example embodiments of the present invention have been shown and described, changes might be made to these example embodiments. The scope of the invention is therefore defined in the following claims and their equivalents.

What is claimed is:

1. A reticle for an OPC test pattern, comprising:
test patterns formed apart from each other at regular intervals; and
dummy patterns for controlling a light transmission amount formed between the test patterns, the dummy patterns being formed apart from the test patterns at a predetermined interval.

2. The reticle of claim 1, wherein the reticle is the same as a chip where an optical proximity correction process is employed in light transmission density.

3. The reticle of claim 1, wherein the interval between the test patterns and the dummy patterns is in a range between about 0.8 μm and about 1.5 μm.

4. The reticle of claim 1, wherein the dummy patterns are formed in a quadrilateral shape.

5. The reticle of claim 1, wherein the dummy patterns are formed at regular intervals in the shape of horizontal or vertical lines.

6. A method of manufacturing a reticle for an OPC test pattern, the method comprising:
forming test patterns apart from each other at regular intervals; and
forming dummy patterns for controlling a light transmission amount in a predetermined shape between the test patterns, the dummy patterns being formed apart from the test patterns at a predetermined interval.

7. The method of claim 6, wherein the interval between the test patterns and the dummy patterns is in a range between about 0.8 μm and about 1.5 μm.

8. The method of claim 6, wherein the dummy patterns are formed at regular intervals in the shape of horizontal or vertical lines.

9. The method of claim 6, wherein the reticle is the same as an OPC application chip in light transmission density.

10. The method of claim 6, wherein the dummy patterns are formed in a quadrilateral shape.
